(19) United States
(12) Patent Application Publication
(10) Pub. No.: US 2010/0207632 A1
(43) Pub. Date: Aug. 19, 2010

(54) RECEIVER FOR MAGNETIC RESONANCE SIGNALS AND METHOD FOR RECEIVING THE MAGNETIC RESONANCE SIGNALS

(76) Inventors: Jian Zhong Li, Shenzhen (CN); Hai Ning Wang, ShenZhen (CN)

Correspondence Address: SCHIFF HARDIN, LLP;PATENT DEPARTMENT, 233 S. Wacker Drive-Suite 6600, CHICAGO, IL, 60606-6473, US

(21) Appl. No.: 12/690,329

(22) Filed: Jan. 20, 2010

(30) Foreign Application Priority Data
Jan. 20, 2009 (CN) 200910000883.5

(51) Int. Cl. G01R 33/44

(52) U.S. Cl. 324/318

(57) ABSTRACT

In a transmission method and receiver for magnetic resonance signals, the receiver has an in vivo coil and an ex vivo coil that are independent of each other. The in vivo coil is disposed within the rectum of a human body for acquiring the magnetic resonance signals generated by the excitation of a radio-frequency transmitter, and transferring the acquired magnetic resonance signals to the ex vivo coil by electromagnetic coupling. The ex vivo coil is to be disposed outside the human body for receiving the magnetic resonance signals from the in vivo coil by the electromagnetic coupling. It is thus not necessary to make a mechanical connection from the in vivo coil to the outside, so it is very convenient for use.

### BACKGROUND OF THE INVENTION

1. Field of the Invention

The present invention relates to the field of magnetic resonance imaging technology and, particularly, to a receiver for magnetic resonance signals and a method for receiving the magnetic resonance signals.

2. Description of the Prior Art

Magnetic resonance imaging (MRI) technology is a non-invasive detecting method for detecting human tissues, and due to its high resolution and absence of bone false images it is capable of carrying out multi-layer and multi-directional scan, forming images in a three-dimensional manner, and presenting clear images of anatomical structures and therefore, it has high value in diagnosing diseases in various systems in a human body. The basic principles of MRI are as follows: the hydrogen atoms within the human tissues (which can also be other atoms, but hydrogen atoms are the most common) produce an oriented arrangement under the effects of a magnetic field; when a radio-frequency transmitting coil is used to apply radio-frequency pulses to human tissues, these hydrogen atoms are deflected under the action of the radio-frequency pulses, and after the radio-frequency pulses have disappeared, all these hydrogen atoms recover their original state; during the recovery process, these hydrogen atoms generate signals, and at this time, a radio-frequency receiving coil is used to acquire the produced signals, then the acquired signals are used to carry out image reconstruction, thereby obtaining an image of the human tissue.

As shown in FIG. 1, an MRI detecting apparatus generally includes a data acquisition unit (scanner) 101, a radio-frequency transmitter 102, one or more receivers 103, an amplifier 104, and an imaging unit 105. The data acquisition unit 101 provides a magnetic field environment needed to generate magnetic resonance, and it can include a permanent magnet, a conventional conductive coil magnet or a superconducting magnet. The radio-frequency transmitter 102 is used to transmit radio-frequency signals, and hydrogen atoms in human tissues are subjected to the excitation of the radio-frequency signals within the magnetic field environment and will produce the magnetic resonance phenomenon. The receiver 103 is used to receive the magnetic resonance signals, and the signals are constructed into a visual image in the imaging unit 105 after having been amplified by the amplifier 104.

When the MRI detecting apparatus is used to carry out examination of a urinary organ in a human body, its receiver needs to be disposed into the rectum of the human body and is generally made into a shape of coil, so it is referred to as a in vivo coil. The current coils in vivo are made of flexible materials, and transmit the acquired signals to the amplifier disposed ex vivo via an output line.

The main disadvantages of the currently available in vivo coils are as follows:

An in vivo coil to be disposed into a human body needs an output mechanically connected to it, thus causing discomfort to the patient and inconvenience to the doctor during use. For safety, it is necessary to additionally fit a radio-frequency choke for suppressing strong pulse signals at the connection of the in vivo coil to the output line, but the volume of such a radio-frequency choke is relatively large, so it is difficult for it to be disposed into the human body together with the in vivo coil, thus the mounting of the radio-frequency choke becomes a problem. Furthermore, since the in vivo coil and the output line are both disposable, it is a waste of the materials.

### SUMMARY OF THE INVENTION

An object of the present invention is to provide a receiver for magnetic resonance signals, having an in vivo coil for which it is unnecessary to make a mechanical connection to the outside.

This object is achieved in accordance with the present invention by a receiver for magnetic resonance signals, having an in vivo coil and an ex vivo coil that are independent of each other, the in vivo coil being configured to be disposed within a human body, so as to acquire the magnetic resonance signals generated by the human body and to transfer the acquired magnetic resonance signals to the ex vivo coil by way of electromagnetic coupling, and the ex vivo coil is configured to be disposed outside the human body, so as to receive the magnetic resonance signals from the in vivo coil by electromagnetic coupling.

The in vivo coil can be a linearly polarized coil.

Alternatively, the in vivo coil can be a circularly polarized coil composed of a number of coil units.

The coil units are linearly polarized coils.

In an embodiment, each linearly polarized coil or coils includes three capacitors connected in parallel.

Each linearly polarized coil can further include a passive detuner, and the passive detuner is connected in parallel to the capacitors of the receiving circuit for protecting the receiving circuit.

In an embodiment, the passive detuner can be formed by an inductor and three diodes, wherein two of the diodes are connected in series to each other and then connected in parallel to another diode in a reversed (oppositely polarized) manner, and the inductor is connected in series to this parallel circuit.

In an embodiment, the ex vivo coil includes an inductor, a diode and two capacitors, wherein the inductor is connected in series to one of the capacitors, and the diode and the other of the capacitors are respectively connected in parallel to this series circuit.

Preferably, the ex vivo coil is a body surface coil or a spine coil.

The present invention also encompasses a method for receiving the magnetic resonance signals, including the steps of receiving, with a coil disposed in vivo within a human body, magnetic resonance signals generated by radio-frequency excitation, and transmitting the magnetic resonance signals from the in vivo coil to an ex vivo coil disposed outside the human body, by electromagnetic coupling.

It can be seen from the above technical solutions that the receiver is composed of an ex vivo coil and an in vivo coil that are independent of each other, and the in vivo coil transfers the magnetic resonance signals to the ex vivo coil by electromagnetic coupling, so it is not necessary to mechanically connect the in vivo coil to the outside. It is thus easy for the in vivo coil to be disposed into the human body, and it is very convenient for use.

### BRIEF DESCRIPTION OF THE DRAWINGS

FIG. 1 is a schematic diagram of a magnetic resonance imaging apparatus in the prior art.

FIG. 2 is a schematic diagram of a receiver for magnetic resonance signals according to a first embodiment of the present invention.

FIG. 3 is a schematic circuit diagram of a in vivo coil which can be applied to the first embodiment of the present invention.

FIG. 4 is a schematic circuit diagram of a ex vivo coil which can be used in the first embodiment of the present invention.

FIG. 5 is a schematic diagram of the equivalent circuit of the in vivo coil shown in FIG. 3, the ex vivo coil shown in FIG. 4 and an amplifier.

FIG. 6 is a schematic diagram of a receiver for magnetic resonance signals according to a second embodiment of the present invention.

FIG. 7 is a schematic diagram of the circuit of a circularly polarized in vivo coil which can be applied in the solutions of the present invention.

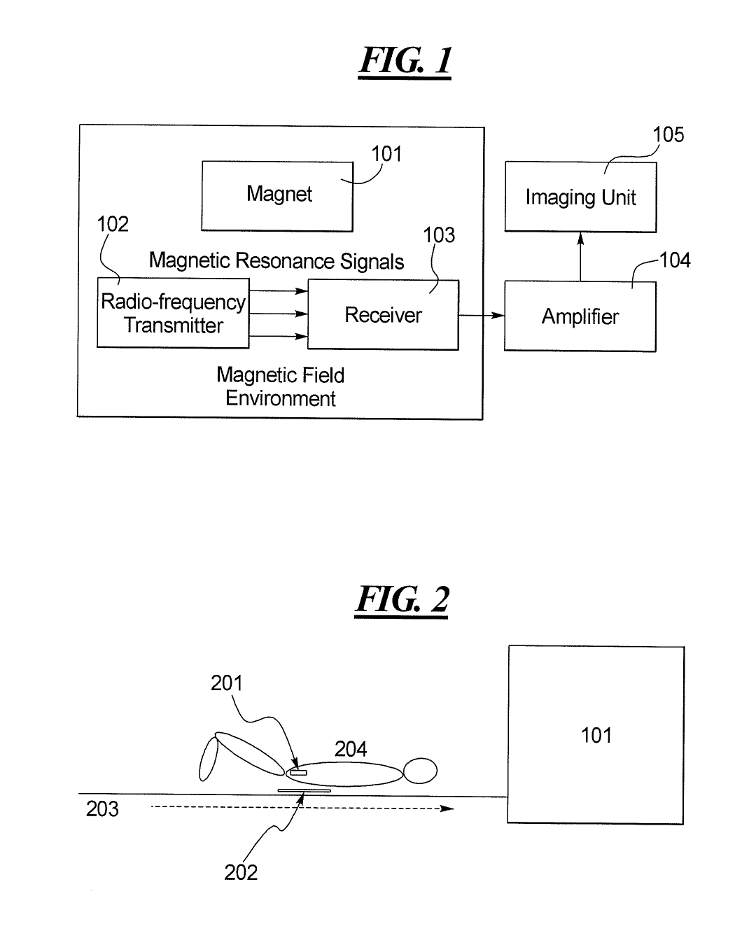

### DESCRIPTION OF THE PREFERRED EMBODIMENTS

The present invention proposes a receiver for magnetic resonance signals, and the receiver is one for a magnetic resonance imaging apparatus. The receiver for magnetic resonance signals comprises an in vivo coil that is to be disposed within a human body when in use and an ex vivo coil that is to be disposed outside the human body when in use, with the in vivo coil and the ex vivo coil not being mechanically connected to each other, but electromagnetically coupled with each other, thus accomplishing the transmission of the magnetic resonance signals acquired by the in vivo coil to the ex vivo coil.

FIG. 2 is a schematic diagram of a receiver which is used for a magnetic resonance imaging apparatus according to the first embodiment of the present invention, as to the magnetic resonance imaging apparatus to which the receiver belongs, all the parts therein except the receiver, such as the radio-frequency transmitter, the amplifier, the imaging unit and the magnet, are the same as those in the prior art, and the other parts of the magnetic resonance imaging apparatus are omitted in FIG. 2, with only the receiver 102 and the magnet 101 shown. The magnet 101 generates a magnetic field in the horizontal direction, and the direction of the magnetic field is represented by a dotted line in FIG. 2. A patient 204 lies flat on a patient bed 203, and the hydrogen atoms within the body of the patient 204 are in a magnetic field environment and will generate magnetic resonance signals under the excitation of the radio-frequency signals transmitted by the radio-frequency transmitter. The receiver has two units which are mechanically independent from each other: an in vivo coil 201 disposed within the rectum of the patient 204; and an ex vivo coil 202 disposed outside the body of the patient 204, with the ex vivo coil 202 capable of being disposed on the patient bed 203 or on the surface of the body of the patient 204. There is no mechanical connection between the in vivo coil 201 and the ex vivo coil 202. The distance between the in vivo coil 201 and the ex vivo coil 202 is about 10 cm, and at such a level of distance, the two coils will generate relatively strong electromagnetic coupling, so that the in vivo coil 201 receives the magnetic resonance signals generated by the hydrogen atoms within the body of the patient 204, and can transmit the received magnetic resonance signals to the ex vivo coil 202 by electromagnetic coupling. There is a circuit connection between the ex vivo coil 202 and the amplifier of the magnetic resonance imaging apparatus, in which the ex vivo coil 202 transmits the signals to the amplifier of the magnetic resonance imaging apparatus, and after having been amplified by the amplifier, the signals are constructed into a visual image in the imaging unit.

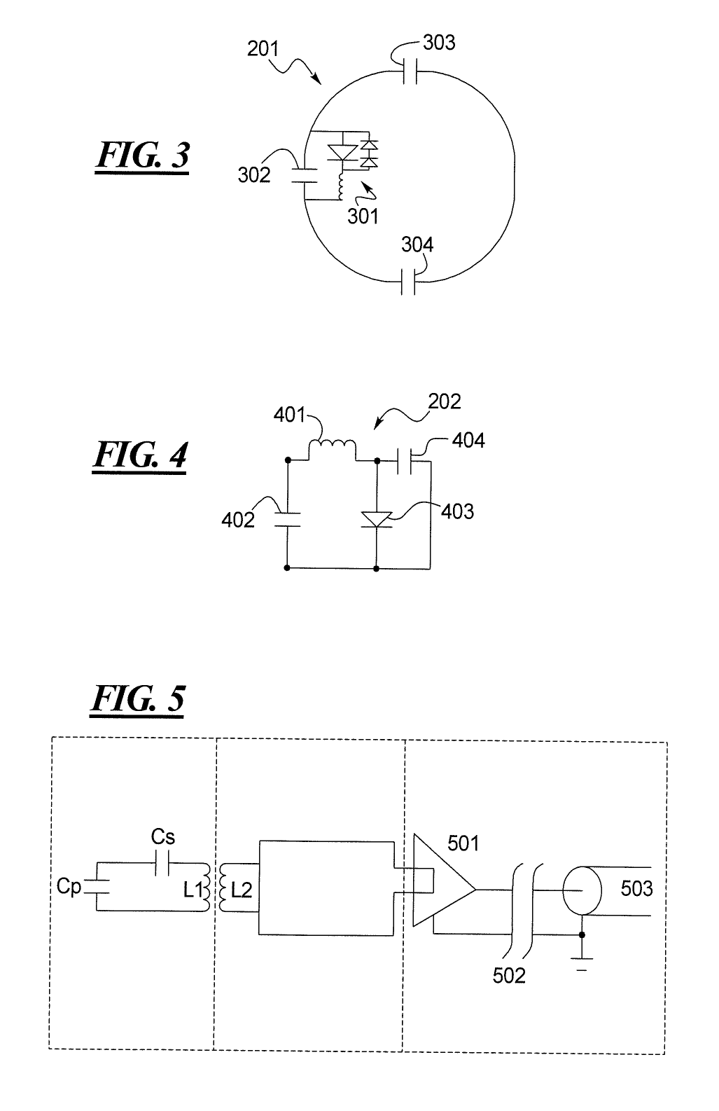

The circuits of the in vivo coil 201 and the ex vivo coil 202 will be described using the particular examples below. FIG. 3 shows an example of the circuit of the in vivo coil 201 which can be used in the first embodiment of the present invention. In this case, the receiving circuit of the in vivo coil 201 includes a capacitor 302, a capacitor 303, a capacitor 304, and conductors between these capacitors, with the capacitors 302, 303 and 304 being connected in parallel. The in vivo coil 201 can also include a passive detuner 301, and the passive detuner 301 is connected in parallel to one of the capacitors (e.g. the capacitor 302), for protecting the circuit of the in vivo coil. For example, the passive detuner 301 has an inductor and three diodes, wherein two of the diodes are connected in series with each other and then they are connected in reverse to the other diode in parallel to form a parallel circuit, and the inductor is connected in series to this parallel circuit. If the signal strength is too high, the diodes in the passive detuner 301 are conductive so as to form a parallel resonance in the in vivo coil 201, thus avoiding damage to the receiving circuit.

FIG. 4 shows an example of the circuit of the ex vivo coil 202 which can be used in the first embodiment of the present invention. The ex vivo coil 202 has a detuning circuit, and the detuning circuit includes an inductor 401, a capacitor 402 and a diode 403, in which the inductor 401 is connected in series to the capacitor 402 to form a series circuit, and the diode 403 is connected in parallel to the series circuit. When the ex vivo coil 202 is in operation, a certain voltage is applied to both sides of the diode 403, so that it is in a short-circuit state, as such, the inductor 401 and the capacitor 402 are in parallel resonance, thus the signals can be transmitted to the amplifier of the magnetic resonance imaging apparatus. The ex vivo coil 202 can further include a capacitor 404, and the capacitor 404 is connected in parallel to the diode 403, which serves to adjust the phases of the signals.

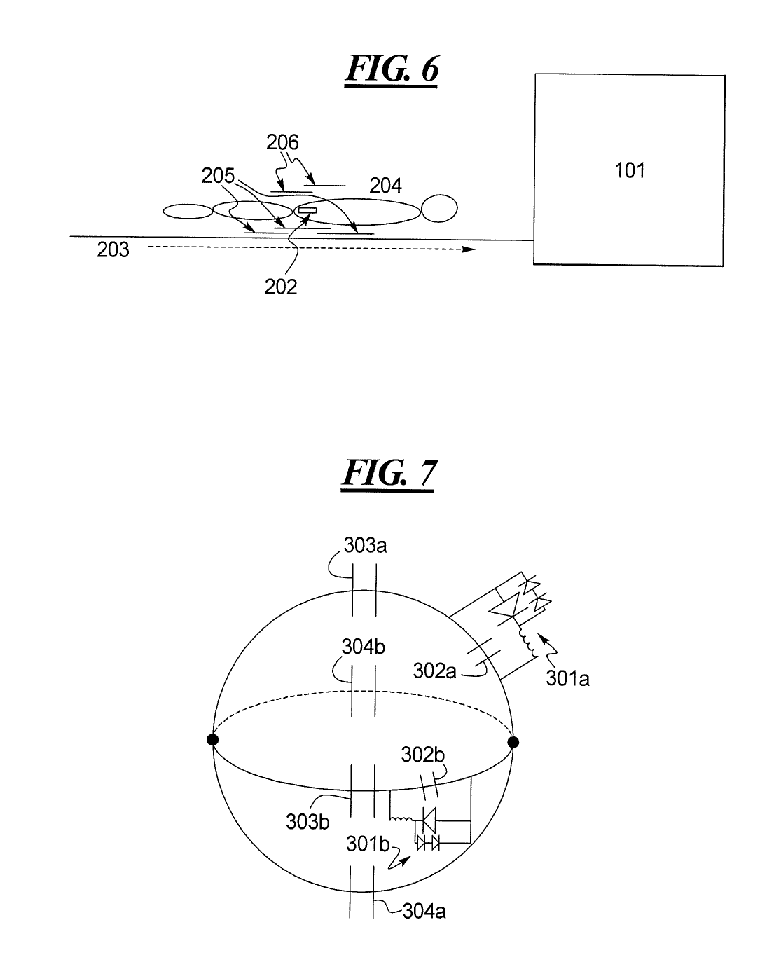

Hereinbelow, it will be explained how to implement electromagnetic coupling between the in vivo coil 201 and the ex vivo coil 202 shown in FIGS. 3 and 4. In this embodiment, the in vivo coil 201 and the ex vivo coil 202 themselves are equivalent to the electromagnetic coupling coils in achieving the electromagnetic coupling therebetween. FIG. 5 shows a schematic diagram of the equivalent circuits of the in vivo coil 201 shown in FIG. 3, the ex vivo coil 202 shown in FIG. 4 and the amplifier. In the leftmost dash-line box, a capacitor Cp, a capacitor Cs and an electromagnetic coupling coil L1 are the equivalent capacitors and the electromagnetic coupling coil of the in vivo coil 201. In the dash-line box in the middle of FIG. 5, the electromagnetic coupling coil L2 is the equivalent electromagnetic coupling coil of the ex vivo coil 202. It is the electromagnetic coupling between L1 and L2 that achieves the transmission of the magnetic resonance signals by the in vivo coil 201 to the ex vivo coil 202.

The dash-line box to the right of FIG. 5 shows the circuit of the amplifier. The amplifier comprises a preamplifier 501, a radio-frequency filter circuit 502 and a radio-frequency signal receiver 503. In this case, the preamplifier 501 amplifies the magnetic resonance signals received from the ex vivo coil 202, the amplified signals are filtered as much as possible of irrelevant noises by the radio-frequency filter circuit 503, and the filtered signals are received by the radio-frequency signal receiver 503.

The circuits of the in vivo coil 201 and the ex vivo coil 202 described above is only an example, and is not intended to limit the present invention.

FIG. 6 is a schematic diagram of a receiver for magnetic resonance signals according to the second embodiment of the present invention. As compared to the first embodiment, the main difference of the receiver is that an existing receiving coil can be used as the ex vivo coil, and the ex vivo coil receives the signals from the in vivo coil in the body by way of electromagnetic coupling. As shown in FIG. 6, the patient 204 lies on the patient bed 203 facing up, and the ex vivo coil can be a spine coil (spine array) 205 disposed on the patient bed 203 and arranged along the direction of the patient's spine, or the ex vivo coil can also be a body surface coil (body array) 206 disposed on the body of the patient 204. Of course, the patient 204 may also lie on the patient bed 203 facing down, and then, the body surface coil 206 is disposed on the patient bed 203, while the spine coil 205 is disposed on the body of the patient 204. Only one ex vivo coil can be used at a time to receive the signals from one part of the patient 204. The patient's local and global images can be acquired by setting various coils ex vivo.

The embodiments of the in vivo coil 201 described above are all linearly polarized coils. In practice, however, the in vivo coil 201 can alternatively be a circularly polarized coil, and FIG. 7 is a schematic diagram of the circuit structure of a circularly polarized coil. The circularly polarized coil in FIG. 7 is composed of two coil units, and black dots at the two sides of FIG. 7 represent crossing points of the coil units, but the coil units are not connected to each other, such that different coil units are distributed in different planes, with each coil unit having the same structure as the linearly polarized coil in FIG. 3. A passive detuner 301a and a passive detuner 301b in FIG. 7 correspond to the passive detuner 301 in FIG. 3, and a capacitor 302a, a capacitor 302b in FIG. 7 correspond to the capacitor 302 in FIG. 3; a capacitor 303a, a capacitor 303b in FIG. 7 correspond to the capacitor 303 in FIG. 3; and a capacitor 304a, a capacitor 304b in FIG. 7 correspond to the capacitor 304 in FIG. 3. The circularly polarized coil can also be composed of more than two coil units. The signals acquired by the circularly polarized coil formed by two or more coil units are relatively intensive, so that the circularly polarized coil has a higher signal-to-noise ratio than that of the linearly polarized coil.

The solutions of the present invention have the following advantages:
1. There is no connection between the in vivo coil and the ex vivo coil, so that it is convenient for use.
2. Since there is no connection between the in vivo coil and the ex vivo coil, it is not necessary to fit a radio-frequency choke, and the problem related to the radio-frequency choke can also be solved completely.
3. Except the in vivo coil disposed into the body, other parts can be reused repeatedly for several times, so costs are saved.

Although modifications and changes may be suggested by those skilled in the art, it is the intention of the inventors to embody within the patent warranted hereon all changes and modifications as reasonably and properly come within the scope of their contribution to the art.

We claim as our invention:

1. A receiver apparatus for magnetic resonance signals comprising:
an in vivo coil configured to be disposed within a human body and configured to detect magnetic resonance signals excited within the human body and to emit electromagnetic radiation representing the detected magnetic resonance signals; and
an ex vivo coil, independent of said in vivo coil, configured to be disposed outside of the human body, and electromagnetically coupled to said in vivo coil to receive said electromagnetic radiation representing said magnetic resonance signals by said electromagnetic coupling.

2. A receiver apparatus as claimed in claim 1 wherein said in vivo coil is configured as a linearly polarized coil.

3. A receiver apparatus as claimed in claim 2 wherein said linearly polarized coil comprises a receiver circuit consisting of three capacitors connected in parallel.

4. A receiver apparatus as claimed in claim 3 wherein said linearly polarized coil comprises a passive detuner, said passive detuner being connected in parallel with said three capacitors of said receiving circuit to protect said three capacitors of said receiving circuit.

5. A receiver apparatus as claimed in claim 4 wherein said passive detuner comprises an inductor and three diodes, two of said three diodes being connected in series with each other, forming a series connection, with said series connection connected in parallel, with opposite polarity, to a third of said three diodes to form a passive detuner parallel circuit, said inductor being connected in series with said passive detuner parallel circuit.

6. A receiver apparatus as claimed in claim 1 wherein said ex vivo coil is configured as circularly polarized coil comprising a plurality of coil units.

7. A receiver apparatus as claimed in claim 6 wherein each of said coil units is configured as a linearly polarized coil.

8. A receiver apparatus as claimed in claim 7 wherein each of said linearly polarized coils comprises a receiver circuit consisting of three capacitors connected in parallel.

9. A receiver apparatus as claimed in claim 8 wherein each of said linearly polarized coils comprise a passive detuner, said passive detuner being connected in parallel with said three capacitors of said receiving circuit to protect said three capacitors of said receiving circuit.

10. A receiver apparatus as claimed in claim 9 wherein said passive detuner comprises an inductor and three diodes, two of said three diodes being connected in series with each other, forming a series connection, with said series connection connected in parallel, with opposite polarity, to a third of said three diodes to form a passive detuner parallel circuit, said inductor being connected in series with said passive detuner parallel circuit.

11. A receiver apparatus as claimed in claim 1 wherein said ex vivo coil comprises an inductor, a diode and two capacitors, said inductor being connected in series with a first of said two capacitors, to form a series circuit, and said diode and a second of said two capacitors being connected in parallel with said series circuit.

12. A receiver apparatus as claimed in claim 1 wherein said ex vivo coil is a coil selected from the group consisting of body surface coils and spine coils.

13. A method for receiving magnetic resonance signals, comprising the steps of:
disposing an in vivo coil within a human body and detecting magnetic resonance signals excited within the human body with said in vivo coil emitting electromagnetic radiation representing the detected magnetic resonance signals from said in vivo coil; and
disposing an ex vivo coil, independent of said in vivo coil, outside of the human body, and electromagnetically coupling said ex vivo coil to said in vivo coil and receiving said electromagnetic radiation representing said magnetic resonance signals with said ex vivo coil by said electromagnetic coupling.
